(19) United States
(12) Patent Application Publication
(10) Pub. No.: US 2024/0269862 A1
(43) Pub. Date: Aug. 15, 2024

(54) SUBSTRATE PROCESSING APPARATUS

(71) Applicant: Tokyo Electron Limited, Tokyo (JP)

(72) Inventor: Takayuki HATANAKA, Miyagi (JP)

(73) Assignee: Tokyo Electron Limited, Tokyo (JP)

(21) Appl. No.: 18/438,519

(22) Filed: Feb. 12, 2024

(30) Foreign Application Priority Data
Feb. 13, 2023 (JP) 2023-020293

(51) Int. Cl. B25J 15/00; B25J 11/00; B25J 19/02; H01L 21/68; H01L 21/687

(52) U.S. Cl. CPC B25J 15/0014; B25J 11/0095; B25J 19/027; H01L 21/68; H01L 21/68707

(57) ABSTRACT

There is a substrate processing apparatus comprising: a vacuum transfer module; a transfer robot disposed in the vacuum transfer module and having an end effector; two capacitance sensors disposed on the end effector; a load-lock module; a substrate processing module connected to the vacuum transfer module; and a controller configured to cause: (a) receiving a substrate with the end effector in the load-lock module; (b) determining a difference between a notch position of the substrate on the end effector and a reference notch position, based on outputs from the two capacitance sensors; and (c) placing the substrate on the end effector on a substrate support in the substrate processing module while adjusting a rotation position of the substrate on the end effector such that the notch position of the substrate on the end effector corresponds to the reference notch position based on the determined difference.

### CROSS-REFERENCE TO RELATED APPLICATION

This application claims priority to Japanese Patent Application No. 2023-020293 filed on Feb. 13, 2023, the entire contents of which are incorporated herein by reference.

### TECHNICAL FIELD

The present disclosure relates to a substrate processing apparatus.

### BACKGROUND

U.S. Laid-open Patent Publication No. 2015/147148 discloses a substrate processing apparatus for processing a substrate or a processing method. As an example of a device configuration, there is disclosed that a transfer robot for placing a substrate on an end effector and transferring the substrate is provided with a sensor for detecting the orientation or the position of a notch formed at the substrate, and the substrate is aligned based on a signal from the sensor.

### SUMMARY

The technique of the present disclosure allows a substrate in a vacuum part to be transferred accurately.

In accordance with an exemplary embodiment of the present disclosure, there is a substrate processing apparatus comprising: a vacuum transfer module; a transfer robot disposed in the vacuum transfer module and having an end effector; two capacitance sensors disposed on the end effector; a load-lock module connected to the vacuum transfer module; a substrate processing module connected to the vacuum transfer module; a substrate support disposed in the substrate processing module; and a controller configured to cause: (a) receiving a substrate with the end effector in the load-lock module; (b) determining a difference between a notch position of the substrate on the end effector and a reference notch position, based on outputs from the two capacitance sensors; and (c) placing the substrate on the end effector on the substrate support in the substrate processing module while adjusting a rotation position of the substrate on the end effector such that the notch position of the substrate on the end effector corresponds to the reference notch position based on the determined difference.

### BRIEF DESCRIPTION OF THE DRAWINGS

FIG. 1 is a plan view showing a configuration example of a substrate processing apparatus according to an embodiment.

FIG. 2 is a plan view showing a configuration example of a transfer arm according to an embodiment.

FIG. 3 is a plan view showing a configuration example of an electrode according to an embodiment.

FIG. 4 is a plan view showing an example of arrangement of a notch of a substrate according to an embodiment.

FIG. 5 is a plan view showing an example of arrangement of the notch of the substrate according to the embodiment.

FIG. 6 is an explanatory diagram showing a system configuration of a capacitance sensor according to an embodiment.

FIG. 7 is an explanatory diagram showing an example of a circuit configuration including a radio frequency oscillator and a C/V conversion circuit according to an embodiment.

FIG. 8 schematically shows an example of arrangement of a notch and electrodes according to an embodiment.

FIG. 9 schematically shows an example of arrangement of a notch of a substrate according to an embodiment.

FIG. 10 schematically shows an example of arrangement of the notch of the substrate according to the embodiment.

FIG. 11 schematically shows an example of arrangement of the notch of the substrate according to the embodiment.

FIG. 12 is a graph showing an example of relationship between a rotation angle and a capacitance.

FIG. 13 is a flowchart showing a configuration example of a substrate processing method according to an embodiment.

FIG. 14 is a flowchart showing a configuration example of a substrate processing method according to an embodiment.

FIG. 15 is an explanatory diagram showing an example in which a capacitance value exceeds a threshold value.

FIG. 16 is a flowchart showing a configuration example of a zero point adjustment method according to an embodiment.

FIG. 17 is a plan view showing another configuration example of a shape of a signal electrode according to an embodiment.

FIG. 18 is a plan view showing a configuration example of a third electrode according to an embodiment.

FIG. 19 is a plan view showing a configuration example of a substrate processing apparatus according to an embodiment.

FIG. 20 is a flowchart showing a configuration example of a substrate processing method according to an embodiment.

### DETAILED DESCRIPTION

In a semiconductor device manufacturing process, a substrate processing module accommodating a semiconductor wafer (hereinafter, referred to as “substrate”) is maintained in a vacuum (decompressed) state, and various processing steps are performed on the substrate. The processing steps are performed using, for example, a substrate processing apparatus in which multiple substrate processing modules are arranged around a common transfer module.

The substrate processing apparatus includes an atmospheric part having an atmospheric module for performing desired processing on a substrate in an atmospheric atmosphere, and a decompression part (vacuum part) having a vacuum (decompression) module for processing a substrate in a vacuum (decompressed) atmosphere. The atmospheric part and the vacuum part (the decompression part) are integrally connected via a load-lock module whose inner atmosphere can be switched between an atmospheric atmosphere and a vacuum (decompressed) atmosphere.

Further, as disclosed in U.S. Laid-open Patent Publication No. 2015/147148, the substrate processing apparatus includes a vacuum transfer robot for transferring a substrate between the load-lock module and each substrate processing module in the transfer module disposed in the vacuum part. The vacuum transfer robot includes an end effector on which a substrate is placed during a transfer operation.

In a conventional substrate processing apparatus, the substrate whose notch orientation has been adjusted in an orienter module disposed in the atmospheric part is transferred to the load-lock module by an atmospheric part transfer robot. Then, the substrate is transferred from the load-lock module to a substrate support in the substrate processing module by the vacuum transfer robot.

In accordance with the sensor disposed on the end effector disclosed in U.S. Laid-open Patent Publication No. 2015/147148, the deviation of the center position and the notch orientation is sensed to correct the operation of the transfer robot.

In the technique of the present disclosure, the rotation deviation is detected to determine a rotation angle. Further, the operation of the transfer robot is corrected based on the amount of the rotation deviation, so that the substrate can be transferred accurately.

Hereinafter, the configuration of the substrate processing apparatus according to the present embodiment will be described with reference to the accompanying drawings. In this specification, like reference numerals will be given to like or corresponding parts, and redundant description thereof will be omitted.

### <Configuration of Substrate Processing Apparatus>

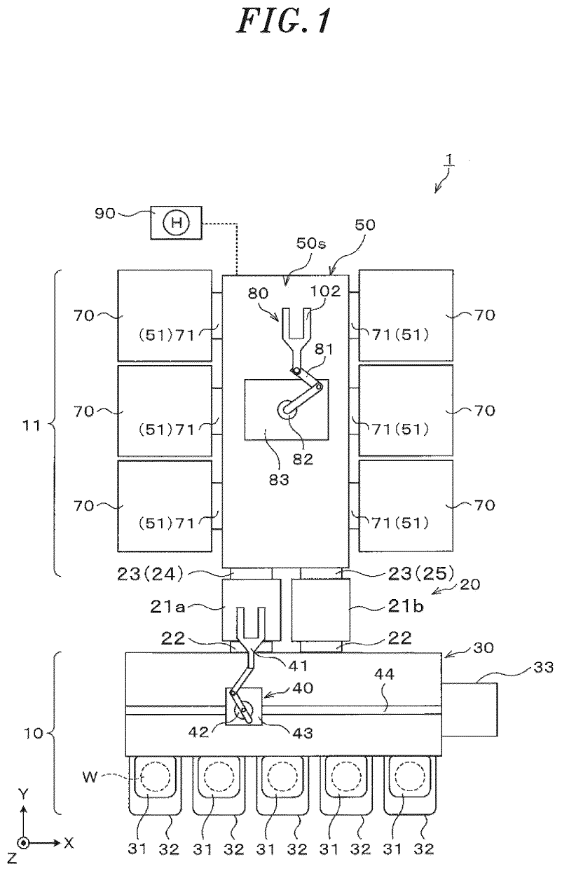

First, a configuration example of a substrate processing apparatus will be described. FIG. 1 is a plan view schematically showing a configuration of a substrate processing apparatus 1 according to an embodiment. In one embodiment, the substrate processing apparatus 1 includes a plasma processing module for performing plasma processing, such as etching, film formation, diffusion, or the like, on a substrate W. The plasma processing module is an example of a substrate processing module. Hereinafter, a case where the substrate processing apparatus 1 includes a plurality of substrate processing modules will be described. However, the module configuration of the substrate processing apparatus 1 of the present disclosure is not limited thereto, and can be arbitrarily selected depending on purposes of the substrate processing.

As shown in FIG. 1, the substrate processing apparatus 1 has a configuration in which an atmospheric part 10 and a decompression part 11 are integrally connected via a load-lock module 20. The atmospheric part 10 includes an atmospheric module for performing desired processing on the substrate W in an atmospheric atmosphere. The decompression part 11 includes a decompression module for performing desired processing on the substrate W in a decompressed atmosphere.

The load-lock module 20 has a plurality of (e.g., two in the present embodiment) substrate transfer chambers 21a and 21b arranged along a width direction (X-axis direction) of a loader module 30 to be described later and a vacuum transfer module 50 to be described later.

The substrate transfer chambers 21a and 21b (hereinafter, may be simply referred to as “substrate transfer chamber 21”) allow communication between the inner space of the loader module 30 (to be described later) of the atmospheric part 10 and the inner space of the vacuum transfer module 50 (to be described later) of the decompression part 11 via substrate transfer ports 22 and 23. The substrate transfer ports 22 and 23 are configured to be opened and closed by gate valves 24 and 25, respectively. A stocker (not shown) for temporarily holding a substrates W transferred between the loader module 30 and the vacuum transfer module 50 is disposed in the substrate transfer chamber 21.

The substrate transfer chamber 21 is configured to temporarily hold the substrate W. Further, the substrate transfer chamber 21 is configured such that the inner atmosphere thereof is switched between an atmospheric atmosphere and a decompressed atmosphere (vacuum state). In other words, the load-lock module 20 is configured to appropriately transfer the substrate W between the atmospheric part 10 maintained in an atmospheric atmosphere and the decompression part 11 maintained in a decompressed atmosphere.

The atmospheric part 10 includes a loader module 30 provided with an atmospheric part transfer robot 40 to be described later, and a load port 32 on which a FOUP 31 capable of storing a plurality of substrates W is placed. The loader module 30 is provided with an orienter module 33 for adjusting a notch position (horizontal direction) of the substrate W. For example, the orienter module 33 detects a notch of the substrate W loaded thereinto, and adjusts a notch position to a desired notch position by rotating the substrate W.

In addition, a storage module (not shown) for storing a plurality of substrates W may be disposed adjacent to the loader module 30.

The loader module 30 has a rectangular housing, and the housing is maintained in an atmospheric atmosphere. A plurality of load ports 32, for example, five load ports 32, are arranged side by side on one side surface constituting the front surface (the longitudinal side in a negative direction of the Y-axis in FIG. 1) of the loader module 30. The substrate transfer chambers 21a and 21b of the load-lock module 20 are arranged side by side on the other side surface constituting the rear surface (the longitudinal side in a positive direction of the Y-axis in FIG. 1) of the loader module 30.

The atmospheric part transfer robot 40 for transferring the substrate W is disposed in the loader module 30. The atmospheric part transfer robot 40 includes a transfer arm 41 for holding and moving the substrate W, a rotatable table 42 for rotatably supporting the transfer arm 41, and a rotatable base 43 on which the rotatable table 42 is placed. Further, a guide rail 44 extending in the longitudinal direction (the X-axis direction in FIG. 1) of the loader module 30 is disposed in the loader module 30. The rotatable base 43 is disposed on the guide rail 44, and the atmospheric part transfer robot 40 is configured to be movable along the guide rail 44. The atmospheric part transfer robot 40 receives the substrate W whose notch orientation has been adjusted to the reference notch position in the orienter module 33, and delivers it to the load-lock module 20 via the inner space of the loader module 30.

The decompression part 11 includes the vacuum transfer module 50 configured to transfer the substrate W in a vacuum environment, and a substrate processing module 70 for performing desired processing on the substrate W transferred from the vacuum transfer module 50. The inner atmospheres of the vacuum transfer module 50 and the substrate processing module 70 can be maintained in a decompressed (vacuum) atmosphere. In the present embodiment, a plurality of (e.g., six) substrate processing modules 70 are connected to one vacuum transfer module 50. The number and arrangement of the substrate processing modules 70 are not limited to those in the present embodiment, and can be set arbitrarily.

The vacuum transfer module 50 is connected to the load-lock module 20. In one embodiment, the vacuum transfer module 50 has a vacuum transfer space 50s and an opening. The opening communicates with the vacuum transfer space 50s, and constitutes a portion to be connected to each module. In the vacuum transfer module 50, the substrate W is transferred between the modules via the vacuum transfer space 50s. For example, the substrate W loaded into the substrate transfer chamber 21a of the load-lock module 20 is transferred to one substrate processing module 70 via the vacuum transfer space 50s. The substrate W is subjected to desired processing in the substrate processing module 70. Thereafter, the substrate W is transferred to the substrate transfer chamber 21b of the load-lock module 20 via the vacuum transfer space 50s, and then transferred to the atmospheric part 10.

A vacuum transfer robot 80 configured to transfer the substrate W is disposed in the vacuum transfer space 50s. In one embodiment, the vacuum transfer robot 80 includes an end effector 102 (to be described later) for holding the substrate W, a transfer arm 81 for moving the end effector 102, a rotatable table 82 for rotatably supporting the transfer arm 81, and a rotatable base 83 on which the rotatable table 82 is placed. In one embodiment, the rotatable base 83 is fixed to the central portion of the vacuum transfer module 50. In one embodiment, the vacuum transfer robot 80 is configured to transfer the substrate between the vacuum transfer space 50s and the load-lock module 20 via the gate valves 24 and 25. Further, in one embodiment, the vacuum transfer robot 80 is configured to transfer the substrate between the vacuum transfer space 50s and the substrate processing space of the substrate processing module 70 via a gate valve 71.

The substrate processing module 70 communicates with the vacuum transfer module 50 via a substrate transfer port 51 formed on the sidewall of the vacuum transfer module 50. The substrate transfer port 51 is configured to be opened and closed by the gate valve 71. A module for performing processing suitable for the purpose of substrate processing can be arbitrarily selected as the substrate processing module 70.

As shown in FIG. 1, the substrate processing apparatus 1 described above includes a controller 90. The controller 90 processes computer-executable instructions for causing the plasma processing apparatus 1 to execute various steps such as transfer or processing of the substrate W described in the present disclosure.

The controller 90 may be configured to control individual components of the plasma processing apparatus 1 to perform various steps described herein. In one embodiment, the controller 90 may be partially or entirely included in the plasma processing apparatus 1. The controller 90 may include a processing part, a storage part, and a communication interface. The controller 90 is realized by, for example, a computer. The processing part may be configured to read a program from the storage part and perform various control operations by executing the read program. The program may be stored in the storage part in advance, or may be obtained via a medium, if necessary. The acquired program is stored in the storage part, and is read from the storage part and executed by the processing part. The medium may be various computer-readable storage media H, or may be a communication line connected to the communication interface. The processing part may be a central processing unit (CPU). The storage part may include a random access memory (RAM), a read only memory (ROM), a hard disk drive (HDD), a solid state drive (SSD), or a combination thereof. The communication interface may communicate with the substrate processing apparatuses 1 and 200 via a communication line such as a local area network (LAN) or the like.

### <End Effector>

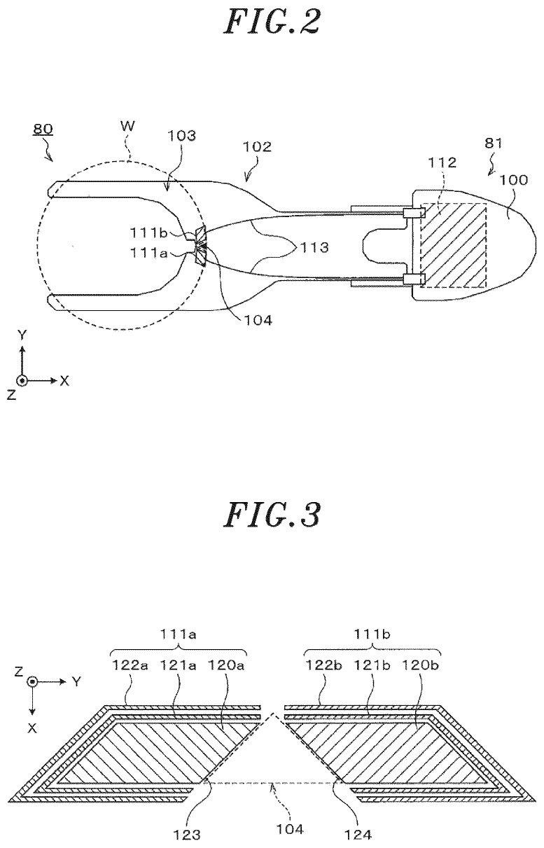

Next, a specific configuration of the end effector 102 in the vacuum transfer robot 80 will be described with reference to FIG. 2. FIG. 2 is a plan view schematically showing the configuration of the end effector 102 according to the present embodiment.

In FIG. 2, the transfer arm 81 includes an arm housing 100, and an end effector 102 is connected to the arm housing 100 at the tip end of the transfer arm 81. A fork is an example of the end effector 102. The end effector 102 has a substrate placing part 103 on which a substrate W is fixedly placed by a desired substrate fixing device (not shown). In FIG. 2, an example of the substrate W placed on the substrate placing part 103 is indicated by a dotted circle. A reference notch position 104 where a notch NC of the substrate W is disposed when the substrate W is placed is defined at the substrate placing part.

When the vacuum transfer robot 80 receives the substrate W temporarily held in the stocker of the substrate transfer chamber 21, the operation thereof is controlled such that the notch NC of the substrate W is located at the reference notch position 104. Such control will be described in detail later.

The vacuum transfer robot 80 includes a notch position detector. The notch position detector includes two capacitance sensors 111a and 111b, a sensor board 112, and a coaxial cable 113 disposed between any one of the sensors and the sensor board 112.

The first capacitance sensor 111a and the second capacitance sensor 111b are adjacent to the reference notch position 104, and are symmetrical (in the example of FIG. 2, line-symmetrical with respect to a line parallel to the X-axis passing through the reference notch position 104) with respect to the reference notch position 104. In the following description, when describing a common configuration, two capacitance sensors may be simply referred to as “capacitance sensor 111” without being distinguished. This is the same when describing a common configuration for individual components included in the capacitance sensor 111.

FIG. 3 is a plan view schematically showing a specific configuration example of the capacitance sensor 111 shown in FIG. 2. In FIG. 3, the first capacitance sensor 111a includes a first signal electrode 120a, a first guard electrode 121a, and a first ground electrode 122a. Further, the second capacitance sensor 111b includes a second signal electrode 120b, a second guard electrode 121b, and a second ground electrode 122b. The first signal electrode 120a and the second signal electrode 120b, the first guard electrode 121a and the second guard electrode 121b, and the first ground electrode 122a and the second ground electrode 122b are disposed to be symmetrical with respect to a line parallel to the X axis passing through the center (for example, the position of the center of gravity in the triangle indicating the reference notch position 104 in FIG. 3) of the reference notch position 104.

Further, in FIG. 3, a guard electrode 121 surrounds the outer sides of three sides of the signal electrode 120 except the side facing the reference notch position 104 in plan view. Further, the ground electrode 122 surrounds the outer side of the guard electrode 121 in plan view. Hereinafter, the side facing the reference notch position 104 of the first signal electrode 120a will be referred to as “left electrode side 123” and the side facing the reference notch position 104 of the second signal electrode 120b will be referred to as “right electrode side 124.” The left electrode side 123 of the first signal electrode 120a extends along the left side of the reference notch position 104, and the right electrode side 124 of the second signal electrode 120b extends along the right side of the reference notch position 104.

The signal electrode 120 is electrically shielded from the outer side of the capacitance sensor 111 in the circumferential direction by the guard electrode 121 and the ground electrode 122. Therefore, the notch position detector can measure a capacitance with high directivity in a direction (e.g., a positive direction of the Z-axis in FIG. 3) in which the signal electrode 120 and the substrate W face each other.

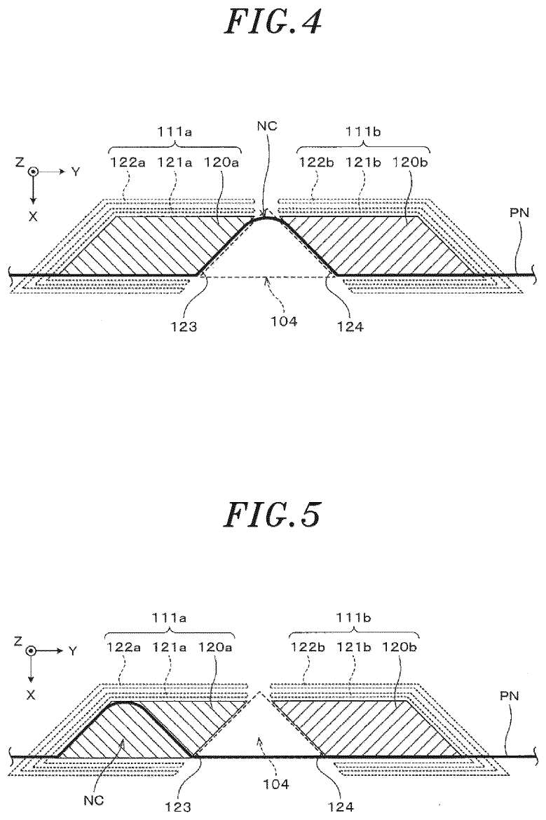

The shape and size of the signal electrode 120 are determined to correspond to those of the notch NC of the substrate W. This shape and size will be described with reference to FIGS. 4 and 5.

FIG. 4 is a plan view showing an example of arrangement in which the notch NC of the substrate W is aligned with the reference notch position 104. A thick line in FIG. 4 indicates a peripheral edge PN of the substrate W including the notch NC. The guard electrode 121 and the ground electrode 122 are indicated by dotted lines for ease of viewing. The portion of the substrate W except the notch NC completely covers the upper surface of the signal electrode 120. On the other hand, the signal electrode 120 is not disposed at the portion where the notch NC is oriented at the reference notch position 104. Further, the straight portions of the peripheral edge PN of the substrate W that constitutes the notch NC are in contact with the left electrode side 123 of the first signal electrode 120a and the right electrode side 124 of the second signal electrode 120b.

FIG. 5 is a plan view showing an example of arrangement in which the notch NC of the substrate W is deviated from the reference notch position 104. The size, shape, and arrangement of the signal electrode 120 are determined such that the signal electrode 120 can completely cover the notch NC of the substrate W when the notch NC is deviated from the reference notch position 104, and does not overlap the notch NC when the notch NC is located at the reference notch position.

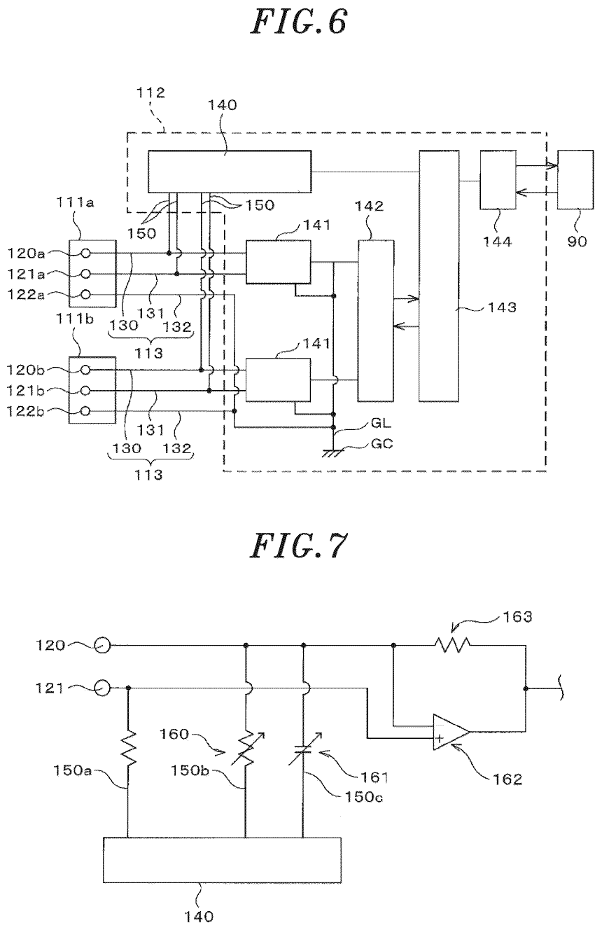

FIG. 6 is an explanatory diagram showing the system configuration of the notch position detector in the vacuum transfer robot 80. As described above, the capacitance sensor 111 is connected to the sensor board 112 by the coaxial cable 113. The sensor board 112 includes a radio frequency (RF) oscillator 140, a C/V conversion circuit 141, an A/D converter 142, a calculation part 143, and a communication part 144.

In FIG. 6, the coaxial cable 113 includes wirings 130 to 132. One end of the wiring 130 is connected to the signal electrode 120. The other end of the wire 130 is connected to an input end of the C/V conversion circuit 141 (to be described later) disposed on the sensor board 112. One end of the wiring 131 is connected to the guard electrode 121. The other end of the wiring 131 is connected to an input end of the C/V conversion circuit 141 (to be described later) disposed on the sensor board 112. One end of the wiring 132 is connected to the ground electrode 122. The other end of the wiring 132 is connected to a ground potential line GL connected to a ground GC of the sensor board 112. The other end of the wiring 132 may be connected to the ground potential line GL via a switch (not shown).

The RF oscillator 140 is connected to a power supply (not shown) such as a battery or an external power supply, and is configured to receive a power from the power supply and generate a radio frequency (RF) signal. The power supply is also connected to the calculation part 143 and the communication part 144. The RF oscillator 140 has a plurality of output lines 150. The RF oscillator 140 is configured to supply the generated RF signal to the wirings 130 and 131 through the output lines 150. Therefore, the RF oscillator 140 is electrically connected to the signal electrode 120 and the guard electrode 121 of the notch position detector, and the RF signal from the RF oscillator 140 is applied to the signal electrode 120 and the guard electrode 121.

The C/V conversion circuit 141 converts the capacitance value between the substrate W and the signal electrode 120 into a voltage value. The specific circuit configuration will be described later.

The output of the C/V conversion circuit 141 is connected to the input of the A/D converter 142. Further, the A/D converter 142 is connected to the calculation part 143. The A/D converter 142 is controlled by a control signal from the calculation part 143, and converts the output signal (voltage signal) of the C/V conversion circuit 141 into a digital value and outputs it as a detection value to the calculation part 143.

The calculation part 143 controls the supply of the RF signal from the RF oscillator 140 to the signal electrode 120 and the guard electrode 121. Specifically, as will be described later, a variable resistor 160 or 161 disposed on the output line 150 is controlled to adjust the amplitude and phase of the RF signal. Further, the calculation part 143 controls power supply from the above-described power supply to individual components.

Further, the calculation part 143 acquires the measurement values of the first capacitance sensor 111a and the second capacitance sensor 111b based on the detection value inputted from the A/D converter 142. In one embodiment, when the detection value outputted from the A/D converter 142 is set to X for the output from any one of the first capacitance sensor 111a and the second capacitance sensor 111b, the calculation part 143 acquires the measurement value based on the detection value such that the measurement value becomes a value that is proportional to (a·X+b). Here, a and b are constants that change depending on a circuit state and the like. The calculation part 143 may, for example, have information on a predetermined expression (function) in which the measurement value becomes a value that is proportional to (a·X+b), and may acquire the measurement value based on the function.

The acquisition of the measurement value in the calculation part 143, which will be described in detail later, is performed for each of the first capacitance sensor 111a and the second capacitance sensor 111b. In one embodiment, the capacitance value in each electrode is acquired from the first capacitance sensor 111a and the second capacitance sensor 111b, and the capacitance values are compared. When the absolute value of the difference between the compared values exceeds a threshold value, it is determined that the rotation deviation has occurred, and a determination signal is outputted to the communication part 144. In one embodiment, the rotation angle is calculated based on the capacitance value, and the calculated rotation angle signal is outputted to the communication part 144. The relationship between the measurement value in the calculation part 143 and the rotation deviation of the substrate W, and a method for determining rotation deviation or calculating a rotation angle will be described later. Further, the calculation part 143 may include a storage part (not shown) that stores the acquired capacitance value, the determination result, the rotation angle value, or the like.

The communication part 144 transmits the determination signal or the rotation angle signal outputted from the calculation part 143 to the outside, e.g., to the controller 90.

FIG. 7 is an explanatory diagram showing a specific circuit configuration including the RF oscillator 140 and the C/V conversion circuit 141 in one embodiment.

In FIG. 7, in one embodiment, a first output line 150a from the RF oscillator 140 is connected to the wiring 131. Further, a second output line 150b and a third output line 150c are connected to the wiring 130. The first output line 150a may have a desired resistance.

The second output line 150b includes a variable resistor 160, and the third output line 150c includes a variable capacitor 161. The variable resistor 160 and the variable capacitor 161 may be known ones whose resistance and capacitance can be controlled by the calculation part 143.

The wiring 130 is connected to an inverting input terminal (−) of an operational amplifier 162, and the wiring 131 is connected to a non-inverting input terminal (+) thereof. Further, a feedback resistor 163 is connected between the output terminal and the inverting input terminal (−) of the operational amplifier 162, and negative feedback is applied to the operational amplifier 162.

In addition, the system configuration disclosed in Japanese Laid-open Patent Publication No. 2022-68582 can be referred to or modified and applied as the system configuration of the notch position detector. Further, the circuit configuration disclosed in Japanese Patent No. 3302377 can be referred to or modified as the circuit configuration including the RF oscillator 140 and the C/V conversion circuit 141.

### <Capacitance Value Calculation Method>

In accordance with the substrate processing apparatus 1 having the above configuration, the capacitance values can be calculated from the first capacitance sensor 111a and the second capacitance sensor 111b. Hereinafter, a specific method for acquiring a capacitance value in each electrode will be described with reference to the drawings.

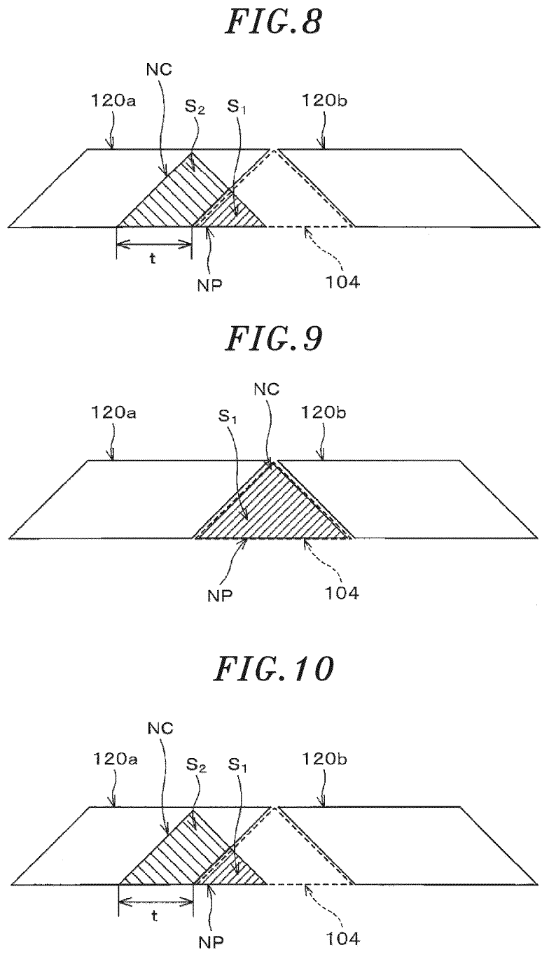

FIG. 8 is an explanatory diagram schematically showing a plan view of the notch NC of the substrate W, the first signal electrode 120a, and the second signal electrode 120b. For convenience of explanation, in the example of FIG. 8, the notch NC is schematically considered as a right-angled isosceles triangle with an area 1 (hypotenuse length 2). Further, the illustration of the guard electrode 121 and the ground electrode 122 is omitted. Hereinafter, the isosceles triangle schematically illustrating the notch NC will be simply referred to as “notch NC,” and the hypotenuse of the isosceles triangle will be referred to as “notch outer periphery NP.” Further, each of the first signal electrode 120a and the second signal electrode 120b is considered as a parallelogram having an area S₀ with diagonal angles of 135° and 45° and a long side length of 2 or more and a short side length of √(2) or more. The first signal electrode 120a and the second signal electrode 120b are arranged with the reference notch position 104 interposed therebetween, as shown in FIG. 8.

FIGS. 9 to 11 are explanatory diagrams showing an example of rotation deviation that occurs when the notch NC moves toward the first signal electrode 120a. In the following drawings, the area of the notch NC that does not face the electrode is set to S₁, and the area of the notch NC that faces the electrode is set to S₂. Further, the moving distance of the outer periphery of the notch NC in the case where the notch NC moves by the rotation deviation, is set to t. Further, the distance between the substrate W and the first signal electrode 120a or the second signal electrode 120b is set to d.

FIG. 9 shows a state in which the first signal electrode 120a and the second signal electrode 120b do not overlap the notch NC, and overlap the substrate W on the entire surface thereof, and a state in which t is 0. In this case, S₁ is 1 and S₂ is 0.

FIG. 10 shows a state in which the notch NC is moving toward the first signal electrode 120a due to rotation deviation of the substrate W, and the moving distance t of the outer periphery of the notch NC is within a range of 0<t<2. In this case, since the area of the notch NC is 1, the area S₂ of the notch NC facing the electrode is expressed by the following Eq. (1).

$${S}_{2} = 1 - {S}_{1} = 1 - ( 1 - t + 1 / 4 {t}^{2} ) = t - 1 / 4 {t}^{2} \qquad Eq . ( 1 )$$

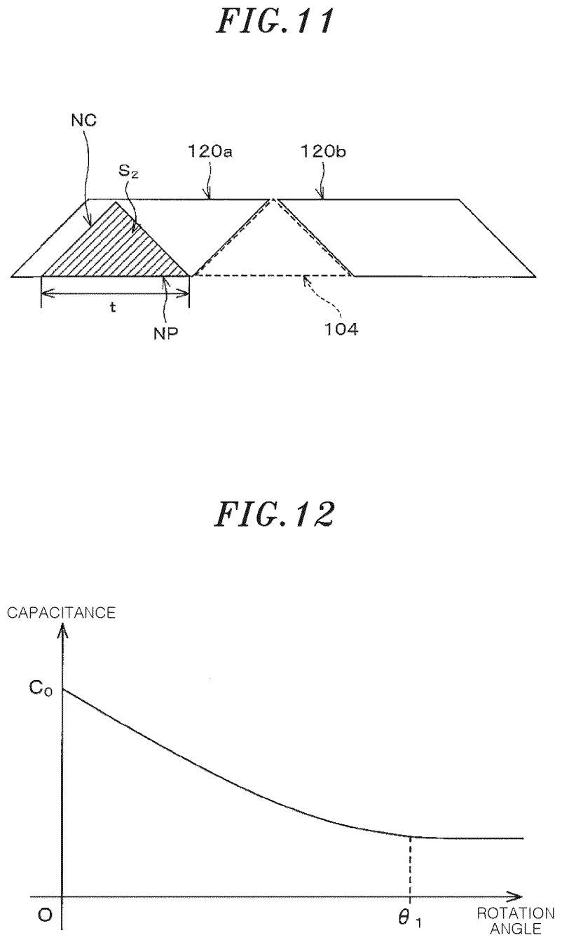

FIG. 11 shows a state in which the notch NC completely overlaps the first signal electrode 120a due to rotation deviation of the substrate W, and a state in which a condition t≥2 is satisfied. In this case, S₁ is 0 and S₂ is 1.

Here, in FIG. 9, when the capacitance between the substrate W and the first signal electrode 120a or the second signal electrode 120b is set to C₀, C₀ is expressed by the following Eq. (2). ε0 indicates the permittivity of vacuum.

$${C}_{0} = ε0 \times ( So / d ) \qquad Eq . ( 2 )$$

In the state shown in FIGS. 9 to 11 where the notch NC is moving toward the first signal electrode 120a, the substrate W overlaps the entire surface of the second signal electrode 120b. Therefore, the capacitance C₂ between the substrate W and the second signal electrode 120b satisfies a condition C₂=C₀.

In the state of FIG. 10 where the length t is within a range 0<t<2, the capacitance C₁ between the substrate W and the first signal electrode 120a is expressed by the following Eq. (3).

$${C}_{1} = {C}_{0} - ε0 \times ( {S}_{2} / d )$$

In the case of substituting Eq. (1) into this, the following equation is obtained.

$${C}_{1} = {C}_{0} - {ε}_{0} / d \times ( t - 1 / 4 {t}^{2} ) \qquad Eq . ( 3 )$$

FIG. 12 is a graph showing the relationship between the rotation angle θ in the rotation deviation obtained based on Eq. (3) and the capacitance C₁ between the substrate W and the first signal electrode 120a. When the moving distance t of the outer periphery of the notch NC is 0, the rotation angle θ is 0. When t is within a range of t>0, the rotation angle can be obtained from the value of t and the diameter of the substrate W. For example, when the rotation angle θ in the case where t is 2 is set to θ1 and the diameter of the substrate W is set to 300, 01 is approximately 0.76°.

In FIG. 12, when the rotation angle θ is within a range of 0≤θ≤θ1, the capacitance C₁ decreases substantially uniformly while satisfying the relationship of Eq. (3). In FIG. 12, when the rotation angle θ is within a range of θ>θ1, the area S₂ of the notch NC facing the electrode does not change after the notch NC completely overlaps the first signal electrode 120a, so that the capacitance C₁ does not change.

Although the case where the substrate W is rotated toward the first signal electrode 120a has been described, the symmetry (line symmetry) of the first signal electrode 120a and the second signal electrode 120b is the same even when the substrate W is rotated toward the second electrode 120b.

### <First Substrate Processing Method>

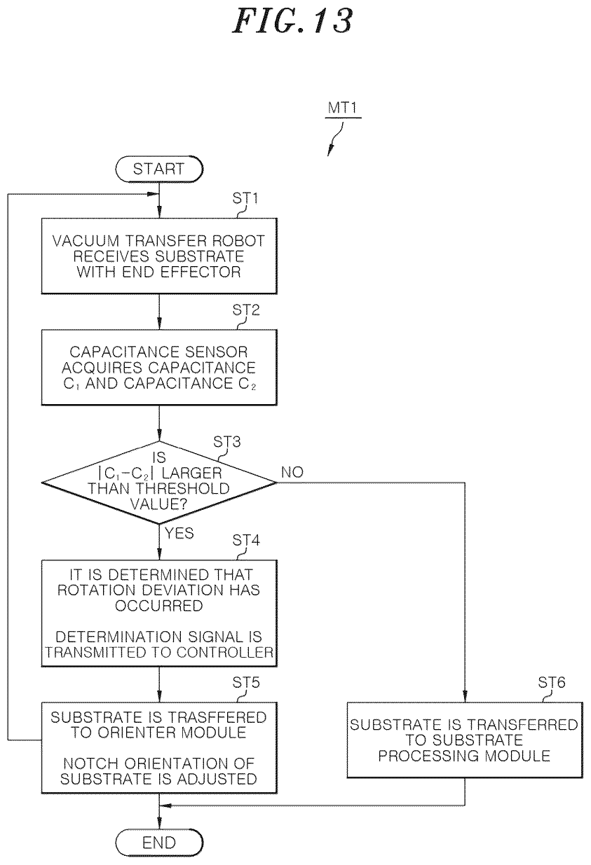

In accordance with the capacitance value calculation method described above, it is determined that the rotation deviation has occurred when the absolute value of the difference between the capacitance C₁ that has decreased due to the rotation deviation and the capacitance C₂ that does not change, which are compared based on Eq. (3), exceeds the threshold value. Hereinafter, a first substrate processing method MT1 that can be performed by determining whether or not rotation deviation has occurred will be described with reference to FIG. 13. FIG. 13 is a flowchart showing a schematic outline of the first substrate processing method MT1.

In step ST1, the vacuum transfer robot 80 receives the substrate W from the load-lock module 20 with the end effector.

In step ST2, the notch position detector acquires the capacitance C₁ and the capacitance C₂.

In step ST3, the calculation part 143 calculates the absolute value of the difference (|C₁−C₂|) between the capacitance C₁ and the capacitance C₂ obtained in step ST2, and compares it with a predetermined threshold value.

When the absolute value of the difference is larger than the threshold value in step ST3, it is determined that rotation deviation has occurred, and the processing proceeds to step ST4. In step ST4, the determination signal outputted from the calculation part 143 is transmitted from the communication part 144 to the controller 90.

In step ST5, the controller 90 that has received the determination signal indicating that rotation deviation has occurred in step ST4 controls the substrate processing apparatus 1 to transfer the substrate W to the orienter module 33, and adjusts the notch orientation of the substrate W again. Then, the substrate W may be transferred to the load-lock module 20 again, and the steps subsequent to step ST1 may be executed again. Otherwise, the processing is terminated.

When the absolute value of the difference is smaller than or equal to the threshold value in step ST3, the processing proceeds to step ST6. In step ST6, it is determined that rotation deviation has not occurred and the notch orientation of the substrate W is normal, and the substrate W is transferred to the substrate processing module 70. Desired processing is performed in the substrate processing module 70, and the processing is terminated.

### <Second Substrate Processing Method>

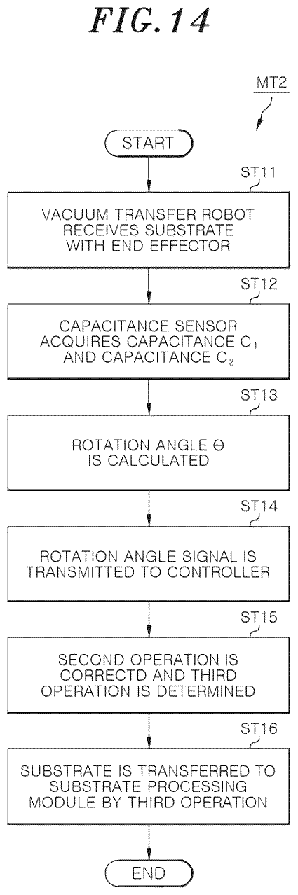

In accordance with the capacitance value calculation method described above, the rotation angle θ can be calculated from the capacitance C₁ based on Eq. (3). Hereinafter, the second substrate processing method MT2 that can be performed by calculating the rotation angle will be described with reference to FIG. 14. FIG. 14 is a flowchart showing a schematic outline of the second substrate processing method MT2.

In step ST11, the vacuum transfer robot 80 receives the substrate W with the end effector from the load-lock module 20 by a first operation. The first operation that is a predetermined control operation of the vacuum transfer robot 80 is stored or executed in the controller 90.

In step ST12, the notch position detector acquires the capacitance C₁ and the capacitance C₂.

In step ST13, the calculation part 143 determines the rotation direction from the capacitance C₁ and the capacitance C₂ obtained in step ST2 to calculate the rotation angle θ. The capacitance C₁ and the capacitance C₂ are compared, and it is determined that the rotation direction of the substrate W is directed toward the first signal electrode 120a when the capacitance C₁ is smaller, and that the rotation direction of the substrate W is directed toward the second signal electrode 120b when the capacitance C₂ is smaller. After the rotation direction is determined, the rotation angle θ is calculated from the capacitance C₁ or the capacitance C₂ based on Eq. (3). The calculation part 143 outputs a rotation angle signal including information on the value of the rotation angle θ to the communication part 144, and the communication part 144 outputs it to the controller 90.

In step ST14, the calculation part 143 outputs a rotation angle signal including information on the value of the rotation angle θ to the communication part 144, and the communication part 144 transmits the rotation angle signal to the controller 90.

In step ST15, the controller 90 corrects a predetermined second operation and determines a third operation based on the rotation angle signal.

In step ST15, the second operation subsequent to the first operation is an operation of the vacuum transfer robot 80 controlled by the controller 90. In the second operation, the substrate W is transferred from the load-lock module 20 to the substrate processing module 70 when the rotation deviation has not occurred and the notch orientation of the substrate W is normal.

In step ST15, the third operation is an operation of transferring the substrate W without rotation deviation that may occur in the substrate support in the substrate processing module 70 in the case where the substrate W is transferred to the substrate processing module 70 without correction by the second operation. In the case of correcting the second operation to the third operation, the position of the notch NC of the substrate W after correction is corrected to a position corresponding to the reference notch position 104 before correction. In this correction, for example, the horizontal rotation angle of the end effector 102 in the second operation is changed based on the rotation angle θ in the rotation deviation.

In step ST16, the substrate W is transferred to the substrate processing module 70 and placed on the substrate support by the third operation determined by correcting the second operation.

In one embodiment, the controller 90 is configured to perform the following steps (a) to (c):
(a) receiving the substrate W with the end effector 102 in the load-lock module 20;
(b) determining the difference between the position of the notch NC of the substrate W on the end effector 102 and the reference notch position 104 based on the outputs from the two capacitance sensors 111a and 111b; and
(c) placing the substrate W on the end effector 102 on the substrate support part in the substrate processing module 70 while adjusting the rotation position of the substrate W on the end effector 102 such that the position of the notch NC of the substrate W on the end effector 102 corresponds to (coincides with) the reference notch position 104 based on the determined difference.

The difference between the position of the notch NC of the substrate W on the end effector 102 and the reference notch position 104 is determined based on the rotation angle θ (i.e., the movement amount of the notch NC of the substrate W from the reference notch position 104).

In accordance with the substrate processing method MT2 configured as described above according to the second embodiment, the rotation angle θ of the substrate W can be calculated even after the substrate W is received by the vacuum transfer robot 80. Further, by correcting the operation of the vacuum transfer robot 80, the substrate W can be transferred such that the notch orientation of the substrate W in the substrate support of the substrate processing module 70 becomes normal.

### <Zero Point Correction of Capacitance Sensor>

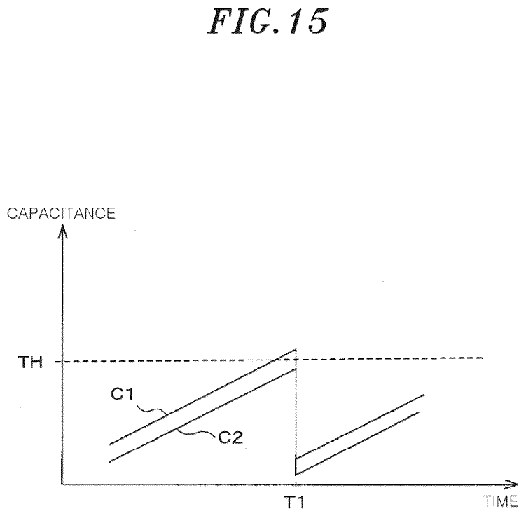

Hereinafter, zero point correction of the notch position detector having the above configuration will be described with reference to FIG. 15. In the notch position detector, the detected capacitance value may change even in a state where there is no detection target or the detection target does not actually change. Therefore, it is preferable to adjust a zero point periodically. For example, as shown in FIG. 15, the zero point adjustment is performed at timing T1 at which the value of the capacitance C₁ or C₂ in the first capacitance sensor 111a or the second capacitance sensor 111b exceeds a threshold value TH. The zero point adjustment is performed in a state where the substrate W is not placed on the end effector 102.

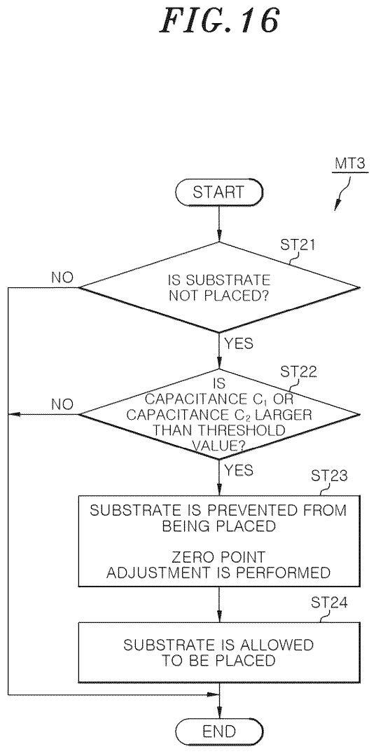

FIG. 16 is a flowchart showing a schematic outline of a zero point adjustment method MT3 of the notch position detector.

In step ST21, it is checked that the substrate W is not placed on the end effector 102. If the substrate W is placed, the substrate W is unloaded and, then, step ST21 is performed again. If the substrate W is not placed, the processing proceeds to step ST22.

In step ST22, any one of the capacitance C₁ of the first capacitance sensor 111a and the capacitance C₂ of the second capacitance sensor 111b is compared with a predetermined threshold value. When neither the capacitance C₁ nor the capacitance C₂ exceeds the threshold value as a result of the comparison, the processing is terminated. Upon completion of the processing, the zero point may be adjusted again after a desired period of time elapses. When any one of the capacitance C₁ and the capacitance C₂ exceeds the threshold value as a result of the comparison, the processing proceeds to step ST23.

In step ST23, the substrate is prevented from being placed on the end effector 102, and the zero point adjustment is performed.

In step ST24, the substrate is allowed to be placed on the end effector 102 and, then, the processing is terminated.

In one embodiment, the zero point adjustment includes synchronization of the phases and the amplitudes of the RF signals in the signal electrode 120 and the guard electrode 121 by controlling the variable resistor 160 and variable capacitor 161 in the C/V conversion circuit 141 shown in FIG. 7. As described above, the RF signal is supplied to the signal electrode 120 and the guard electrode 121 by the RF oscillator 140. In this case, if the phases and the amplitudes of the RF signals in the signal electrode 120 and the guard electrode 121 are shifted, the output voltage at the output terminal side of the operational amplifier 162 changes over time. By controlling the variable resistor 160 and the variable capacitor 161, and synchronizing the phases and the amplitudes of the RF signals in the signal electrode 120 and the guard electrode 121, the output voltage at the output terminal side of the operational amplifier 162 can be stabilized.

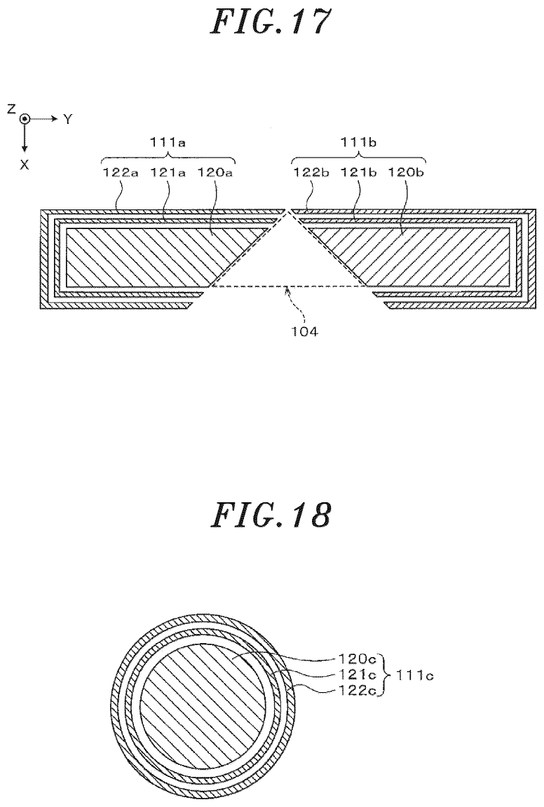

Although the above embodiment has described an example in which the signal electrode 120 has a parallelogram shape, the shape of the signal electrode 120 of the present disclosure is not limited thereto. FIG. 17 is a plan view schematically showing an example of another shape of the signal electrode 120.

In FIG. 17, each of the first signal electrode 120a and the second signal electrode 120b has a trapezoidal shape, and is line-symmetrical with respect to the reference notch position 104. The substrate processing methods MT1 and MT2 can be performed even if the angle in contact with the side opposite to the side facing the reference notch position 104 is changed to a desired angle.

Although the above embodiment has described an example in which two capacitance sensors 111 are provided as the notch position detector has been described, the number of the capacitance sensors 111 is not limited thereto. FIG. 18 is a plan view schematically showing a configuration of a third capacitance sensor 111c that is further included in the notch position detector in addition to the first capacitance sensor 111a and the second capacitance sensor 111b.

In FIG. 18, the third capacitance sensor 111c includes a third signal electrode 120c, a third guard electrode 121c surrounding the third signal electrode 120c, and a third ground electrode 122c surrounding the third guard electrode 121c. Similarly to other capacitance sensors 111, the third capacitance sensor 111c is connected to the sensor board 112 by each wiring included in a third coaxial cable 113c. Unlike the first capacitance sensor 111a and the second capacitance sensor 111b, the entire circumference of the third signal electrode 120c is surrounded by the third guard electrode 121c. In accordance with the third capacitance sensor 111c, it is possible to measure the capacitance with higher directivity in a direction (for example, in the positive direction of the Z-axis in FIG. 18) in which the third signal electrode 120c and the substrate W face each other.

The third capacitance sensor 111c is provided such that the area of the third signal electrode 120c becomes the same as the area of each of the first signal electrode 120a and the second signal electrode 120b. The third capacitance sensor 111c is disposed at a position where it constantly faces the substrate W when the substrate W is placed on the end effector 102.

In accordance with the notch position detector including the third capacitance sensor 111c, in the case of calculating the capacitance, the capacitance calculated in the third capacitance sensor 111c can be used as the capacitance C₀ obtained when the entire surface of the first signal electrode 120a or the second signal electrode 120b is covered with the substrate W. By using the capacitance of the third capacitance sensor 111c as the reference capacitance C₀, the capacitances C₁ and C₂ can be calculated more accurately.

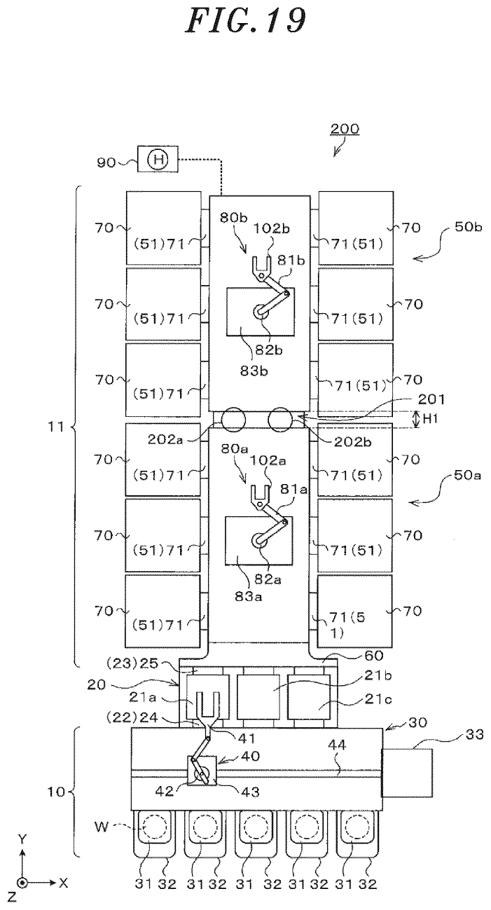

Hereinafter, a substrate processing apparatus 200 according to an embodiment will be described with reference to FIG. 19. The substrate processing apparatus 200 includes a first vacuum transfer module 50a and a second vacuum transfer module 50b that are connected by a path module 201. Each of the first vacuum transfer module 50a and the second vacuum transfer module 50b has the same configuration as that of the vacuum transfer module 50 of the substrate processing apparatus 1 in the example of FIG. 1 except the path module 201. In other words, both the first vacuum transfer module 50a and the second vacuum transfer module 50b have a configuration that allows the capacitance to be calculated or the substrate processing methods MT1 and MT2 to be performed. In one embodiment, the substrate processing apparatus 200 or the path module 201 has substantially the same configuration as that of the substrate processing apparatus 200 or the path module described in Japanese Laid-open Patent Publication No. 2022-104056. Further, the path module 201 includes substrate supports 202a and 202b (hereinafter, may be simply referred to as “substrate support 202”), each having a rotation mechanism therein. The substrates W placed on the substrate supports 202a and 202b can be rotated by a rotation mechanism, so that the notch orientation thereof can be adjusted.

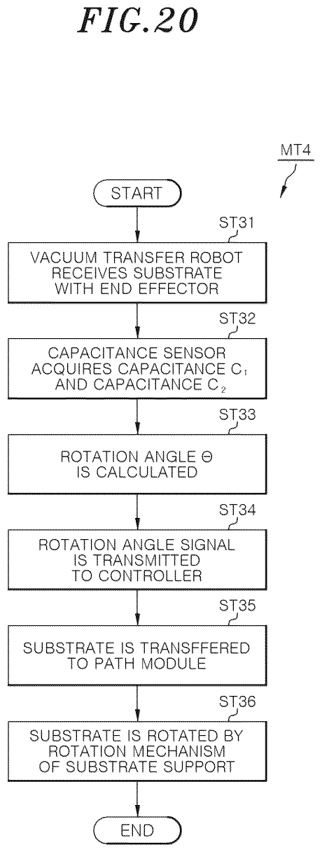

In accordance with the substrate processing apparatus 200 configured as described above, a following substrate processing method MT4 can be performed. FIG. 20 is a flowchart showing an outline of the substrate processing method MT4.

In step ST31, the first vacuum transfer robot 80a receives the substrate W from the load-lock module 20 with a first end effector 102a of the first transfer arm 81a.

In step ST32, the capacitance C₁ and the capacitance C₂ are acquired by the notch position detector in the first transfer end effector 102a.

In step ST33, the calculation part 143 determines the rotation direction from the capacitance C₁ and the capacitance C₂ obtained in step ST32 to calculate the rotation angle θ. The capacitance C₁ and capacitance C₂ are compared, and it is determined that the rotation direction of substrate W is directed toward the first signal electrode 120a when the capacitance C₁ is smaller, and the rotation direction of the substrate W is directed toward the second signal electrode 120b when the capacitance C₂ is smaller. After the rotation direction is determined, the rotation angle θ is calculated from the capacitance C₁ or the capacitance C₂ based on Eq. (3). The calculation part 143 outputs the rotation angle signal including information on the value of the rotation angle θ to the communication part 144 and the communication part 144 outputs it to the controller 90.

In step ST34, the calculation part 143 outputs the rotation angle signal including information on the value of the rotation angle θ to the communication part 144, and the communication part 144 transmits the rotation angle signal to the controller 90.

In step ST35, the controller 90 controls the first vacuum transfer robot 80a to transfer the substrate W to the substrate support 202a of the path module 201.

In step ST36, the controller 90 controls the rotation mechanism of the substrate support 202a based on the rotation angle signal to rotate the substrate W such that the position of the notch NC corresponds to the reference notch position 104. Then, the processing is terminated.

After the above substrate processing method is completed, the first vacuum transfer robot 80a may receive the substrate W again, and transfer it to the substrate processing module 70 connected to the first vacuum transfer module 50a so that desired processing can be performed on the substrate W. Further, the second vacuum transfer robot 80b may receive the substrate W again, and transfer it to the substrate processing module 70 connected to the second vacuum transfer module 50b so that desired processing can be performed on the substrate W.

In one embodiment, the controller 90 is configured to perform the following steps (a) to (e):
(a) receiving the substrate W with the first end effector 102a in the load-lock module 20;
(b) determining the difference between the position of the notch NC of the substrate W on the first end effector 102a and the reference notch position 104 based on the outputs from the two capacitance sensors 111a and 111b;
(c) placing the substrate W on the first end effector 102a on the substrate support 202 in the path module 201;
(d) rotating the substrate W on the substrate support 202 in the path module 201 such that the position of the notch NC of the substrate W on the substrate support 202 in the path module 201 corresponds to (coincides with) the reference notch position 104 based on the determined difference; and
(e) receiving the substrate W on the substrate support 202 in the path module 201 with the second end effector 102b.

The rotation of the substrate W on the substrate support 202 in the path module 201 is performed by the rotation mechanism of the substrate support 202 in the path module 201.

In accordance with the substrate processing method MT4 described above, the rotation angle θ of the substrate W can be calculated even after the substrate W is received by the vacuum transfer robot 80. Further, the substrate W can be rotated based on the calculated rotation angle θ by the substrate support disposed in the path module such that the notch orientation of the substrate W becomes normal.

In one embodiment, the controller 90 is configured to perform the following steps (a) to (d):
(a) receiving the substrate W with the first end effector 102a in the load-lock module 20;
(b) determining the difference between the position of the notch NC of the substrate W on the first end effector 102a and the reference notch position 104 based on the outputs from the two capacitance sensors 111a and 111b;
(c) placing the substrate W on the first end effector 102a on the substrate support 202 in the path module 201 while adjusting the rotation position of the substrate W on the first end effector 102a such that the position of the notch NC of the substrate W on the first end effector 102a corresponds to the reference notch position 104 based on the determined difference; and
(d) receiving the substrate W on the substrate support 202 in the path module 201 with the second end effector 102b.

It should be noted that the above-described embodiments are illustrative in all respects and are not restrictive. The above-described embodiments may be omitted, replaced, or changed in various forms without departing from the scope of the appended claims and the gist thereof. For example, the components of the above-described embodiments can be randomly combined. The effects of the components for arbitrary combination can be obtained from the corresponding arbitrary combination, other effects apparent to those skilled in the art can also be obtained.

The effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

1. A substrate processing apparatus comprising:
a vacuum transfer module;
a transfer robot disposed in the vacuum transfer module and having an end effector;
two capacitance sensors disposed on the end effector;
a load-lock module connected to the vacuum transfer module;
a substrate processing module connected to the vacuum transfer module;
a substrate support disposed in the substrate processing module; and
a controller configured to cause:
(a) receiving a substrate with the end effector in the load-lock module;
(b) determining a difference between a notch position of the substrate on the end effector and a reference notch position, based on outputs from the two capacitance sensors; and
(c) placing the substrate on the end effector on the substrate support in the substrate processing module while adjusting a rotation position of the substrate on the end effector such that the notch position of the substrate on the end effector corresponds to the reference notch position based on the determined difference.

2. The substrate processing apparatus of claim 1, wherein the two capacitance sensors are disposed on the end effector to surround the reference notch position on the end effector.

3. The substrate processing apparatus of claim 2, wherein the two capacitance sensors include a first capacitance sensor and a second capacitance sensor,
the first capacitance sensor is disposed at a left part with respect to the reference notch position, and has a first signal electrode with a left electrode side extending along a left side of the reference notch position, and
the second capacitance sensor is disposed at a right part with respect to the reference notch position, and has a second signal electrode with a right electrode side extending along a right side of the reference notch position.

4. The substrate processing apparatus of claim 3, wherein the left electrode side and the right electrode side are arranged to form a V shape in plan view.

5. The substrate processing apparatus of claim 3, wherein the first capacitance sensor has a first guard electrode and a first ground electrode,
the first guard electrode surrounds the first signal electrode,
the first ground electrode surrounds the first guard electrode,
the second capacitance sensor has a second guard electrode and a second ground electrode,
the second guard electrode surrounds the second signal electrode, and
the second ground electrode surrounds the second guard electrode.

6. The substrate processing apparatus of claim 3, wherein the first capacitance sensor has a first guard electrode and a first ground electrode,
the first guard electrode surrounds sides of the first signal electrode except the left electrode side of the first signal electrode,
the first ground electrode surrounds the first guard electrode,
the second capacitance sensor has a second guard electrode and a second ground electrode,
the second guard electrode surrounds sides of the second signal electrode except the right electrode side of the second signal electrode, and
the second ground electrode surrounds the second guard electrode.

7. The substrate processing apparatus of claim 3, wherein the first signal electrode and the second signal electrode have a parallelogram shape in plan view.

8. The substrate processing apparatus of claim 3, wherein the first signal electrode and the second signal electrode have a trapezoidal shape in plan view.

9. A substrate processing apparatus comprising:
a first vacuum transfer module;
a first transfer robot disposed in the first vacuum transfer module and having a first end effector;
two capacitance sensors disposed on the first end effector;
a load-lock module connected to the first vacuum transfer module;
a second vacuum transfer module;
a second transfer robot disposed in the second vacuum transfer module and having a second end effector;
a path module disposed between the first vacuum transfer module and the second vacuum transfer module;
a substrate support disposed in the path module; and
a controller configured to cause:
(a) receiving a substrate with the first end effector in the load-lock module;
(b) determining a difference between a notch position of the substrate on the first end effector and a reference notch position, based on outputs from the two capacitance sensors;
(c) placing the substrate on the first end effector on the substrate support in the path module while adjusting a rotation position of the substrate on the first end effector such that the notch position of the substrate on the first end effector corresponds to the reference notch position based on the determined difference; and
(d) receiving the substrate on the substrate support in the path module with the second end effector.

10. The substrate processing apparatus of claim 9, wherein the two capacitance sensors are disposed on the first end effector to surround the reference notch position on the first end effector.

11. The substrate processing apparatus of claim 10, wherein the two capacitance sensors include a first capacitance sensor and a second capacitance sensor,
the first capacitance sensor is disposed at a left part with respect to the reference notch position, and has a first signal electrode with a left electrode side extending along a left side of the reference notch position, and
the second capacitance sensor is disposed at a right part with respect to the reference notch position, and has a second signal electrode with a right electrode side extending along a right side of the reference notch position.

12. The substrate processing apparatus of claim 11, wherein the left electrode side and the right electrode side are arranged to form a V shape in plan view.

13. The substrate processing apparatus of claim 12, wherein the first capacitance sensor has a first guard electrode and a first ground electrode,
the first guard electrode surrounds the first signal electrode,
the first ground electrode surrounds the first guard electrode,
the second capacitance sensor has a second guard electrode and a second ground electrode,
the second guard electrode surrounds the second signal electrode, and
the second ground electrode surrounds the second guard electrode.

14. A substrate processing apparatus comprising:
a first vacuum transfer module;
a first transfer robot disposed in the first vacuum transfer module and having a first end effector;
two capacitance sensors disposed on the first end effector;
a load-lock module connected to the first vacuum transfer module;
a second vacuum transfer module;
a second transfer robot disposed in the second vacuum transfer module and having a second end effector;
a path module disposed between the first vacuum transfer module and the second vacuum transfer module;
a substrate support disposed in the path module; and
a controller configured to cause:
(a) receiving a substrate with the first end effector in the load-lock module;
(b) determining a difference between a notch position of the substrate on the first end effector and a reference notch position, based on outputs from the two capacitance sensors;
(c) placing the substrate on the first end effector on the substrate support in the path module;
(d) rotating the substrate on the substrate support such that the notch position of the substrate on the substrate support corresponds to the reference notch position based on the determined difference; and
(e) receiving the substrate on the substrate support in the path module with the second end effector.

15. The substrate processing apparatus of claim 14, wherein the two capacitance sensors are arranged on the first end effector to surround the reference notch position on the first end effector.

16. The substrate processing apparatus of claim 15, wherein the two capacitance sensors include a first capacitance sensor and a second capacitance sensor,
the first capacitance sensor is disposed at a left part with respect to the reference notch position, and has a first signal electrode with a left electrode side extending along a left side of the reference notch position, and
the second capacitance sensor is disposed at a right part with respect to the reference notch position, and has a second signal electrode with a right electrode side extending along a right side of the reference notch position.

17. The substrate processing apparatus of claim 16, wherein the left electrode side and the right electrode side are arranged to form a V shape in plan view.

18. The substrate processing apparatus of claim 17, wherein the first capacitance sensor has a first guard electrode and a first ground electrode,
the first guard electrode surrounds the first signal electrode,
the first ground electrode surrounds the first guard electrode,
the second capacitance sensor has a second guard electrode and a second ground electrode,
the second guard electrode surrounds the second signal electrode, and
the second ground electrode surrounds the second guard electrode.
